(19) United States
(12) Patent Application Publication
(10) Pub. No.: US 2026/0089911 A1
(43) Pub. Date: Mar. 26, 2026

(54) SEMICONDUCTOR DEVICE AND METHOD FOR FABRICATING THE SAME

(71) Applicant: NANYA TECHNOLOGY CORPORATION, New Taipei City (TW)

(72) Inventors: Chen-Hao LIEN, New Taipei City (TW); Yao-Hsiung KUNG, New Taipei City (TW)

(21) Appl. No.: 18/895,380

(22) Filed: Sep. 25, 2024

(51) Int. Cl. H10B 12/00

(52) U.S. Cl. CPC H10B 12/033; H10B 12/315

(57) ABSTRACT

A method of fabricating a semiconductor device that includes providing an initial structure, where the initial structure includes a bit line structure, a landing pad adjacent to the bit line structure, and an isolation layer adjacent to the landing pad, depositing a first dielectric layer on the initial structure, modifying an etch property of the first dielectric layer, performing an etching process on the first dielectric layer to form a first opening, and forming a capacitor structure in the first opening.

### BACKGROUND

Dynamic random-access memory (dynamic RAM or DRAM) is a type of random-access semiconductor memory that stores each bit of data in a memory cell. DRAM is known for its high speed operation, high density, and scalability. However, as the production of DRAM scales up, the manufacturing of DRAM becomes more challenging and more prone to defects. The defects may cause device errors and/or failures. For example, possible electrical short can happen in a DRAM when the overlay of a container and a landing pad shifts. Therefore, there is a need for a credible apparatus and fabrication method for a semiconductor device.

### SUMMARY

The disclosure provides a method of fabricating a semiconductor device that includes providing an initial structure, where the initial structure includes a bit line structure, a landing pad adjacent to the bit line structure, and an isolation layer adjacent to the landing pad, depositing a first dielectric layer on the initial structure, modifying an etch property of the first dielectric layer, performing an etching process on the first dielectric layer to form a first opening, and forming a capacitor structure in the first opening.

In some embodiments, modifying the etch property of the first dielectric layer comprises implanting an impurity species into the first dielectric layer.

In some embodiments, the impurity species is germanium (Ge).

In some embodiments, implanting the impurity species into the first dielectric layer is performed with an energy in a range from approximately 20KeV to approximately 25KeV.

In some embodiments, implanting the impurity species into the first dielectric layer is performed with a dose of Ge in a range from approximately 3x10¹⁶ (ion/cm²) to approximately 5x10¹⁶ (ion/cm²).

In some embodiments, the impurity species is nitrogen (N).

In some embodiments, implanting the impurity species into the first dielectric layer is performed with an energy in a range from approximately 6KeV to 11KeV.

In some embodiments, implanting the impurity species into the first dielectric layer is performed with a dose of N in a range from approximately 3x10¹⁶ (ion/cm²) to approximately 5x10¹⁶ (ion/cm²).

In some embodiments, the first dielectric layer and the isolation layer are made with a same material, and wherein modifying the etch property of the first dielectric layer is performed such that the isolation layer has a higher etch resistance to the etching process than the first dielectric layer.

In some embodiments, the method further includes depositing a second dielectric layer on the first dielectric layer, in which the etching process is also performed on the second dielectric layer, such that the first opening is formed in both the first dielectric layer and the second dielectric layer.

The disclosure provides a semiconductor device that includes a bit line structure, a landing pad adjacent to the bit line structure, an isolation layer adjacent to the landing pad, a first dielectric layer on the isolation layer and the landing pad, in which the first dielectric layer has a higher germanium (Ge) concentration or a higher nitrogen (N) concentration than the isolation layer, and a capacitor structure in the first dielectric layer.

In some embodiments, the isolation layer and the first dielectric layer are made with a same material.

In some embodiments, the same material is silicon nitride.

In some embodiments, the capacitor structure is in the second dielectric layer.

In some embodiments, the second dielectric layer comprises a vertical thickness, and wherein the vertical thickness is greater than a vertical thickness of the first dielectric layer.

In some embodiments, the capacitor structure is in contact with the isolation layer and the landing pad.

In some embodiments, a lateral width of the capacitor structure is greater than a lateral width of a top surface of the landing pad.

In some embodiments, the semiconductor device further includes a bit line spacer along a sidewall of the bit line structure, wherein the bit line spacer is made of a same material as the first dielectric layer.

In some embodiments, the first dielectric layer has a higher Ge concentration than the bit line spacer.

In some embodiments, the first dielectric layer has a higher N concentration than the bit line spacer.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic view of a memory array, in accordance with some embodiments of the present disclosure.

FIG. 2 is a schematic view of a memory cell, in accordance with some embodiments of the present disclosure.

FIG. 3 is a flow chart of a method of fabricating a semiconductor device, in accordance with some embodiments of the present disclosure.

FIG. 4 is a flow chart of patterning the first and second dielectric layers in a method of fabricating a semiconductor device, in accordance with some embodiments of the present disclosure.

FIGS. 5 to 17 are cross-sectional views of different steps of a method of fabricating a semiconductor device, in accordance with some embodiments of the present disclosure.

FIG. 18 is a cross-sectional view of a memory cell, in accordance with some embodiments of the present disclosure.

### DETAILED DESCRIPTION

Various example embodiments will be described more fully hereinafter with reference to the accompanying drawings, in which some example embodiments are shown. The present disclosure may, however, be embodied in many different forms and should not be construed as limited to the example embodiments set forth herein. Rather, these example embodiments are provided so that this disclosure will be thorough and complete, and will fully convey the scope of the present disclosure to those skilled in the art. It is noted that, in accordance with the standard practice in the industry, various features are not drawn to scale. In fact, the dimensions of the various features may be arbitrarily increased or reduced for clarity of discussion.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

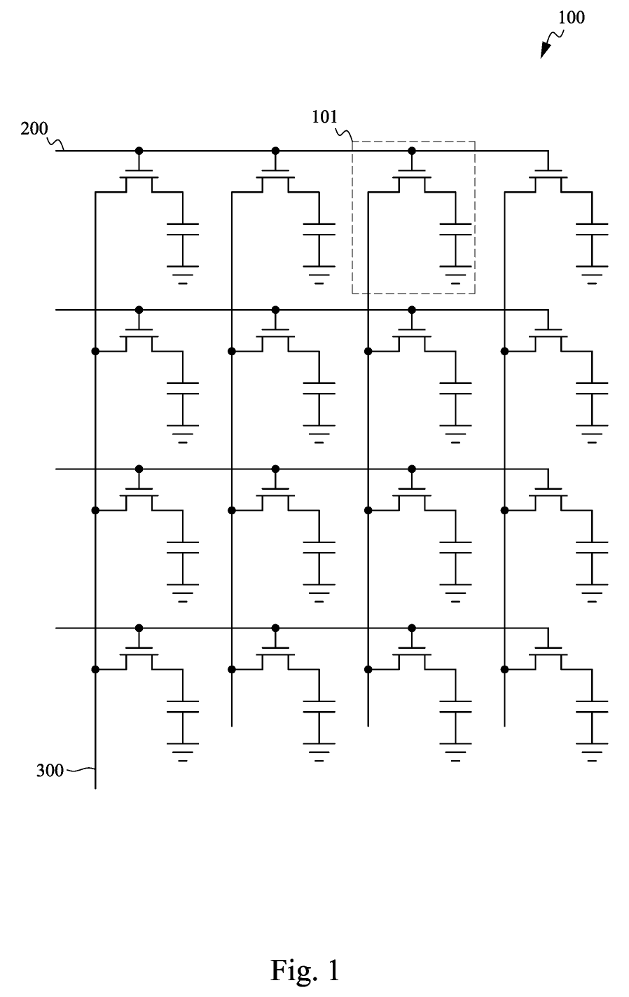

FIG. 1 is a schematic view of a memory array, in accordance with some embodiments of the present disclosure. In some embodiments, the memory array 100 includes multiple memory cells 101 laid out in a rectangular matrix. FIG. 1 shows a simple example with a four-by-four cell matrix. Other memory matrices many be thousands of cells in height and width. In some embodiments, the memory array 100 can be a dynamic random-access memory (dynamic RAM or DRAM).

Each row of memory cells 101 is connected by a word line 200 and each column of memory cells 101 is connected by a bit line 300. A plurality of word lines 200 may extend horizontally. The word lines 200 are parallel to each other. Additionally, the word lines 200 may be spaced apart from each other at substantially equal intervals. On the other side, a plurality of bit lines 300 may extend vertically. Similar to the word lines 200, the bit lines 300 are parallel to each other and may be spaced apart from each other at substantially equal intervals.

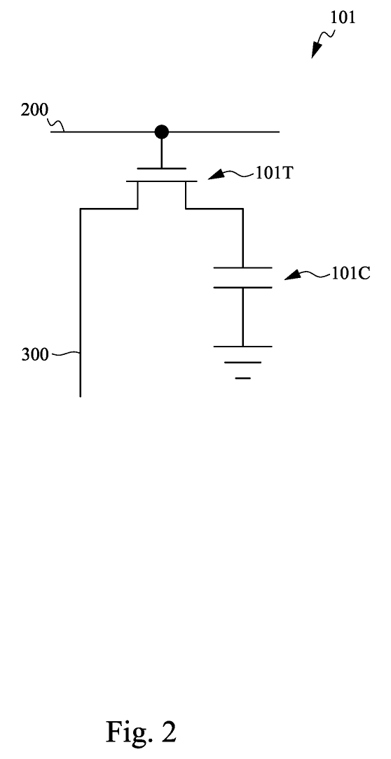

FIG. 2 is a schematic view of a memory cell, in accordance with some embodiments of the present disclosure. Specifically, FIG. 2 is a close-up view of FIG. 1. In some embodiments, a memory cell 101 includes an access transistor 101T and a storage capacitor 101C electrically connected to the access transistor 101T. In some embodiments, the access transistor 101T is an NMOS transistor, and is configured to control the channel to the memory cell 101 by opening or closing the gate of the access transistor 101T. In some embodiments, the storage capacitor 101C is configured to store information according to the state of electrical charges stored therein. The storage capacitor 101C in an empty state, that is, no charge, is denoted a logic value of 0. The storage capacitor 101C in a fully-charged state is denoted a logic value of 1. The memory cell 101 stores a bit of data by means of the two extreme states of charges stored in the storage capacitor 101C. In some embodiments, a word line 200 connected to the access transistor 101T is used to control the gate of the access transistor 101T by applying a voltage to the gate of the access transistor 101T. In some embodiments, a bit line 300 is arranged perpendicular to the word line 200 and is also connected to the access transistor 101T. When the gate of the access transistor 101T is turned on, the access transistor 101T connects the storage capacitor 101C to the bit line 300 such that the logic value stored in the storage capacitor 101C will be read on the bit line 300.

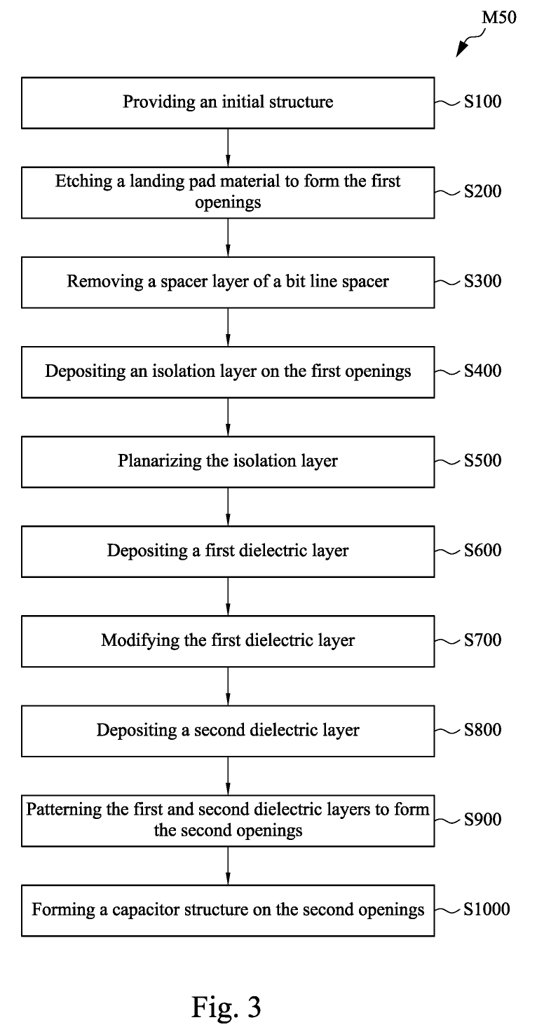

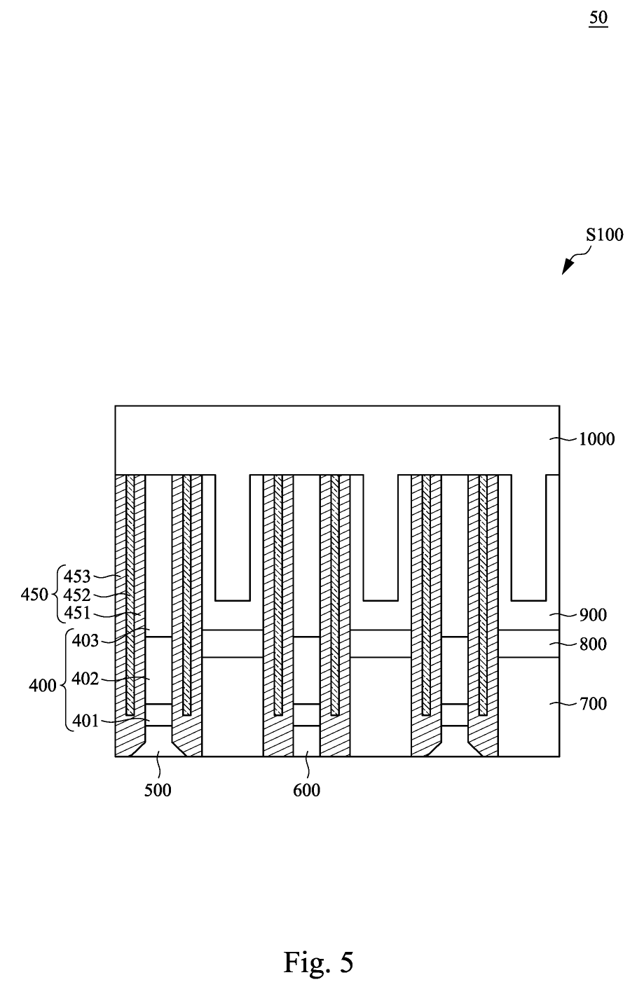

FIG. 3 is a flow chart of a method of fabricating a semiconductor device, in accordance with some embodiments of the present disclosure. FIGS. 5 to 17 are cross-sectional views of different steps of a method of fabricating a semiconductor device, in accordance with some embodiments of the present disclosure.

The fabricating method M50 of FIG. 3 can be applied by a semiconductor device. The semiconductor device and the fabricating method M50 will be discussed in conjunction with reference to FIGS. 5 to 17. As illustrated in FIG. 3, a fabricating method M50 may include the following operations S100, S200, S300, S400, S500, S600, S700, S800, S900, and S1000.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

The method M50 starts from operation S100 by providing an initial structure. Referring to FIG. 5, in some embodiments, an initial structure 50 includes a bit line structure 400, a bit line spacer 450, a dielectric layer 500, a contact layer 600, a contact plug 700, a conductive layer 800, a barrier 900, and a landing pad material 1000. In some embodiments, the bit line structure 400 includes a first bit line conductive layer 401, a second bit line conductive layer 402 over the first bit line conductive layer 401, and a capping layer 403 over the second bit line conductive layer 402. In some embodiments, the bit line spacer 450 includes a first spacer layer 451, a second spacer layer 452, and a third spacer layer 453, in which the second spacer layer 452 is between the first spacer layer 451 and the third spacer layer 453.

In some embodiments, an initial structure 50 includes a plurality of bit line structures 400. A plurality of bit line structures 400 protrudes upward from a substrate (not shown). Specifically, the bit line structures 400 are located above the dielectric layer 500 or contact layer 600 on top of the substrate. The bit line structures 400 may extend vertically from the dielectric layer 500 or contact layer 600 and are parallel to each other. In some embodiments, the bit line structures 400 may be regularly arranged at substantially equal intervals from each other.

The formation of the first bit line conductive layer 401, second bit line conductive layer 402, and the capping layer 403 may include forming two conductive material layers and a dielectric material capping layer sequentially over the dielectric layer 500 or the contact layer 600. In some embodiments, an etching process may be performed to the two conductive material layers and the dielectric material capping layer, so each of the bit line structure 400 can be spaced apart from each other horizontally and extend in parallel with each other vertically.

The first bit line conductive layer 401 and the second bit line conductive layer 402 are made with different conductive materials. In some embodiments, the first bit line conductive layer 401 and second bit line conductive layer 402 are made with metal, metal nitride, or metal silicide. In some embodiments, the first bit line conductive layer 401 and second bit line conductive layer 402 may include doped polysilicon, tungsten, tungsten nitride, and/or titanium nitride. A vertical length of the second bit line conductive layer 402 may be greater than that of the first bit line conductive layer 401.

The capping layer 403 is made with dielectric material. In some embodiments, the capping layer 403 includes silicon nitride. A vertical length of the capping layer 403 may be greater than that of the first bit line conductive layer 401 or the second bit line conductive layer 402.

The dielectric layer 500 and the contact layer 600 are located on the substrate and are below the first bit line conductive layer 401. The first bit line conductive layer 401 may either have a dielectric layer 500 or a contact layer 600 in between itself and the substrate, but not both. The dielectric layer 500 is configured to provide an electrical isolation between at least one bit line structure 400 and the underlying structure in the substrate (not shown). The dielectric layer 500 is made with a dielectric material.

On the other side, the contact layer 600 is configured to provide an electrical connection between the bit line structure 400 and an underlying structure in the substrate, such as an access transistor (not shown). The contact layer 600 is made with a conductive material. The contact layer 600 may be in contact with the first bit line conductive layer 401.

A bit line spacer 450 is located around the bit line structure 400 horizontally. Particularly, the bit line spacer 450 extends along a sidewall of the bit line structure 400. The bit line spacer 450 may include a first spacer layer 451, a second spacer layer 452, and a third spacer layer 453 located around the bit line structure 400. The bit line spacer 450 is configured to electrically isolate the bit line structure 400 from the adjacent structures, such as the contact plug 700, the conductive layer 800, and the landing pad material 1000.

In some embodiments, the second spacer layer 452 can be used as a sacrificial layer for transforming into an air gap in the subsequent fabrication steps.Consequently, the second spacer layer 452 may have an etch selectivity with respect to the first spacer layer 451 and/or the third spacer layer 453. In other words,during the same etching process, an etching rate on the second spacer layer 452 is faster than that on the first spacer layer 451 and/or the third spacer layer 453.

In some embodiments, the first spacer layer 451, the second spacer layer 452, and the third spacer layer 453 include dielectric material. In some embodiments, the first spacer layer 451 includes silicon nitride. In some embodiments, the second spacer layer 452 includes oxides, such as silicon oxide. In some embodiments, the third spacer layer 453 includes silicon nitride. Based on the disclosure herein, other materials, as discussed above, can be used, and these materials are within the spirit and scope of this disclosure.

A contact plug 700 is located horizontally in between two bit line spacers 450 and vertically below the conductive layer 800. The contact plug 700 may be electrically connected to the underlying structure, such as an access transistor in the substrate (not shown). The contact plug 700 may be made with a conductive material. In some embodiments, the contact plug 700 includes doped polysilicon.

A conductive layer 800 is located horizontally in between two bit line spacers 450 and vertically in between the contact plug 700 and the barrier 900. The conductive layer 800 may be made with a conductive material. In some embodiments, the conductive layers 800 include metal nitride or metal. In some embodiments, the conductive layers 800 include tungsten, tungsten nitride, and/or titanium nitride.

A barrier 900 is located horizontally in between two bit line spacers 450 and vertically in between the contact plug 700 and the landing pad material 1000. The barrier 900 may be made with a conductive material.

A landing pad material 1000 is located above the barriers 900 and may overlap at least a portion of a corresponding bit line structure 400 and at least a portion of a corresponding bit line spacer 450. In some embodiments, the landing pad material 1000 may include several portions extending between two bit line spacers 450, and such portions are surrounded by the respective barriers 900. The landing pad material 1000 may be made with a conductive material. The landing pad material 1000 is configured in a conventional dynamic random access memory (DRAM) cells for a purpose of electrical interconnection to the following formed.

The above description sums up an initial structure 50. However, not all items in the initial structure 50 are necessary in some embodiments.

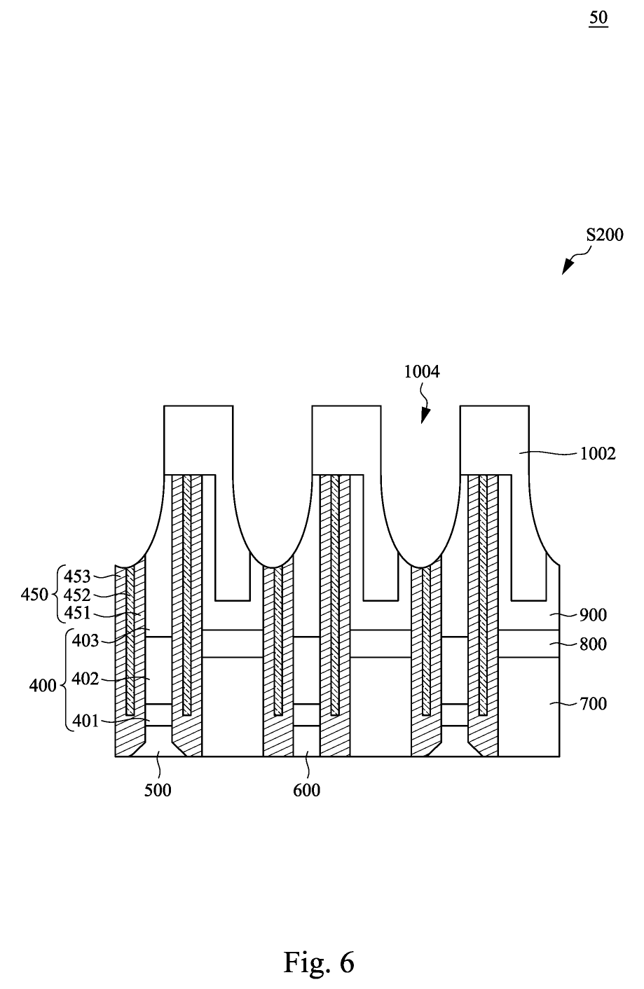

The method M50 proceeds to operation S200 by etching a landing pad material to form the first openings. Referring to FIG. 6, a mask pattern (not shown) may be formed on the landing pad material 1000. Subsequently, the landing pad material 1000 is etched through the mask pattern to form the first openings 1004 in the landing pad material 1000, and the first openings 1004 divide the landing pad material 1000 into several landing pads 1002. In some embodiments, a portion of the barrier 900, bit line spacer 450, and capping layer 403 may be removed as well. After etching, the landing pads 1002 may be separated from each other by first openings 1004, in which each first opening 1004 may expose the respective bit line spacer 450.

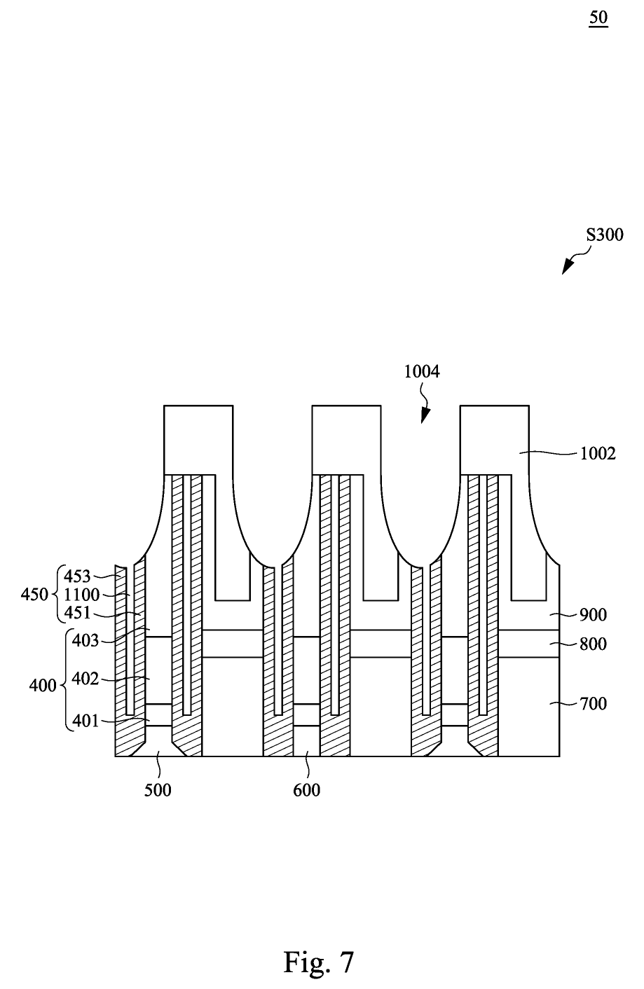

The method M50 proceeds to operation S300 by removing a spacer layer of a bit line spacer. Referring to FIG. 7, the second spacer layers 452 of the bit line spacers 450 are selectively removed and consequently air gaps 1100 are formed within the bit line spacers 450. The air gap 1100 is formed between the first spacer layer 451 and the third spacer layer 453. Therefore, the bit line spacer 450 may now include a first spacer layer 451, an air gap 1100, and a third spacer layer 453.

The removal of the second spacer layer 452 may include a selective etching. The second spacer layer 452 which includes an oxide has a different etch selectivity with respect to the first spacer layer 451 and the third spacer layer 453. In other words, the etching rate on the second spacer layer 452 may be higher than that on the first spacer layer 451 and the third spacer layer 453. In some embodiments, a vapor etch process is applied for the second spacer layer 452. In some embodiments, the vapor etch process includes hydrogen fluoride.

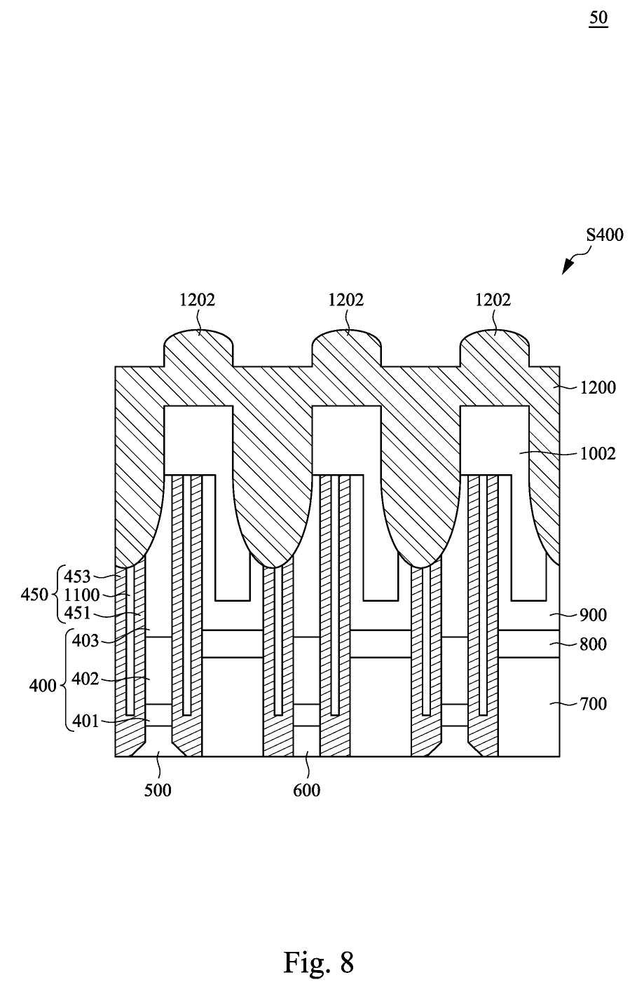

The method M50 proceeds to operation S400 by depositing an isolation layer on the first openings. Referring to FIG. 8, an isolation layer 1200 is deposited into the first openings 1004, and the air gaps 1100 are capped with the isolation layer 1200, and the isolation layer 1200 cover at least a portion of the landing pad 1002, at least a portion of the barrier 900, at least a portion of the bit line spacer 450 and/or at least a portion of the capping layer 403. In other words, the isolation layer 1200 replaces the first openings 1004.

The isolation layer 1200 can be deposited by any suitable deposition processes such as chemical vapor deposition (CVD), plasma-enhanced chemical vapor deposition (PECVD), atomic layer deposition (ALD), physical vapor deposition (PVD), low-pressure chemical vapor deposition (LPCVD), flowable chemical vapor deposition (FCVD), or other suitable processes.

In some embodiments, the isolation layer 1200 may include a dielectric material. In some embodiments, the isolation layer 1200 may include silicon nitride (SiN). In some embodiments, the isolation layer 1200 may include a material substantially the same as the first spacer layer 451 or the third spacer layer 453. In some embodiments, the isolation layer 1200 may seal the air gaps 1100 within the bit line spacers 450.

In some embodiments, the isolation layer 1200 may not be flat, but may include a plurality of protrusions 1202. The protrusions 1202 may result from the deposition process on an uneven surface. In some embodiments, some of the isolation layer 1200 may be deposited on the lower levels such as the first openings 1004, while some of the isolation layer 1200 may be deposited on the higher levels such as the top surface of the landing pads 1002. Therefore, a plurality of protrusions 1202 may be formed above the top surface of the landing pads 1002.

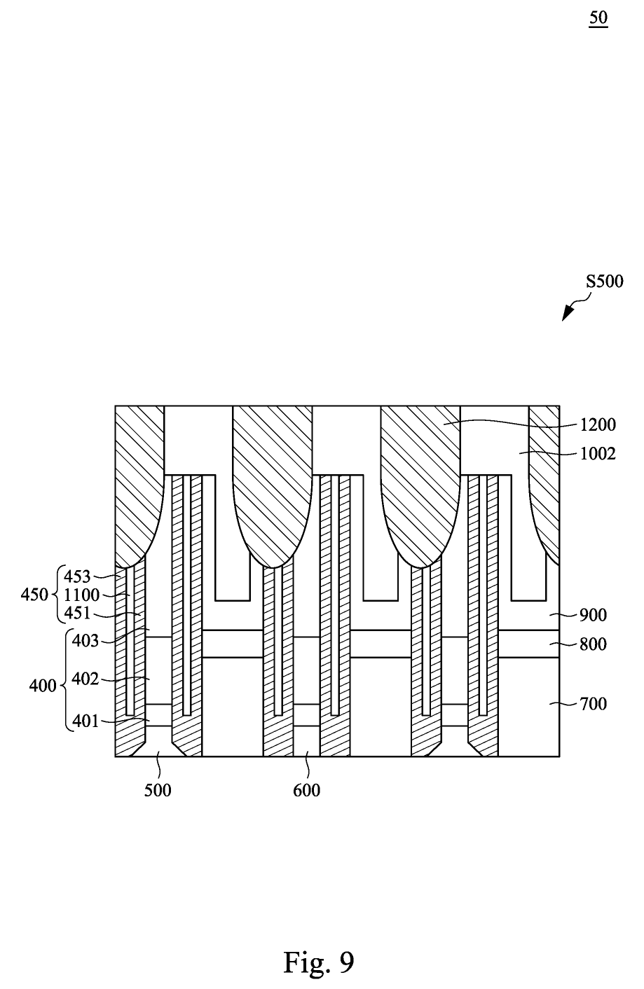

The method M50 proceeds to operation S500 by planarizing the isolation layer. Referring to FIG. 9, a planarization process is performed to remove excess material of the isolation layer 1200, so as to level the isolation layer 1200 with the landing pads 1002. The leveled isolation layer 1200 is coplanar to the landing pads 1002, therefore share the same top surface. That is, the top surface the isolation layer 1200 and the top surfaces of the landing pads 1002 may be coterminous with each other. A chemical mechanical polishing (CMP) process can be used for the planarization process. The CMP process may keep performing until a signal from one of materials included in the landing pad 1002 is detected.

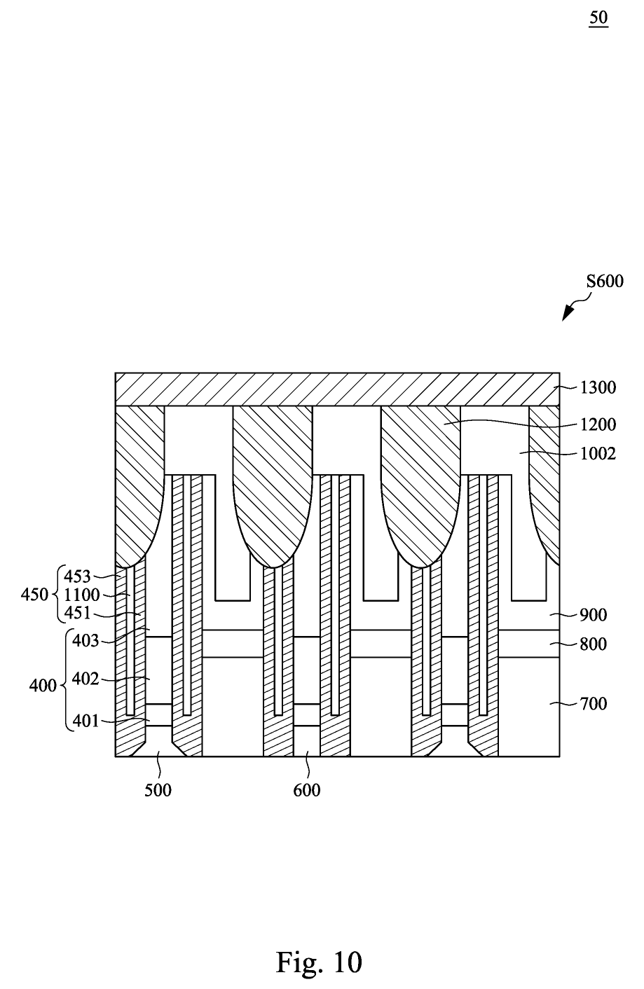

The method M50 proceeds to operation S600 by depositing a first dielectric layer. Referring to FIG. 10, a first dielectric layer 1300 is formed on the leveled isolation layer 1200 and the landing pads 1002. The first dielectric layer 1300 can be deposited by using CVD, ALD, PVD, or other suitable deposition processes. In some embodiments, the first dielectric layer 1300 may include dielectric material. In some embodiments, the first dielectric layer 1300 may include silicon nitride (SiN). In some embodiments, the first dielectric layer 1300 may include the same material as the isolation layer 1200, the first spacer layer 451, and the third spacer layer 453. In some embodiments, the first dielectric layer 1300 has a vertical length of approximately 20nm.

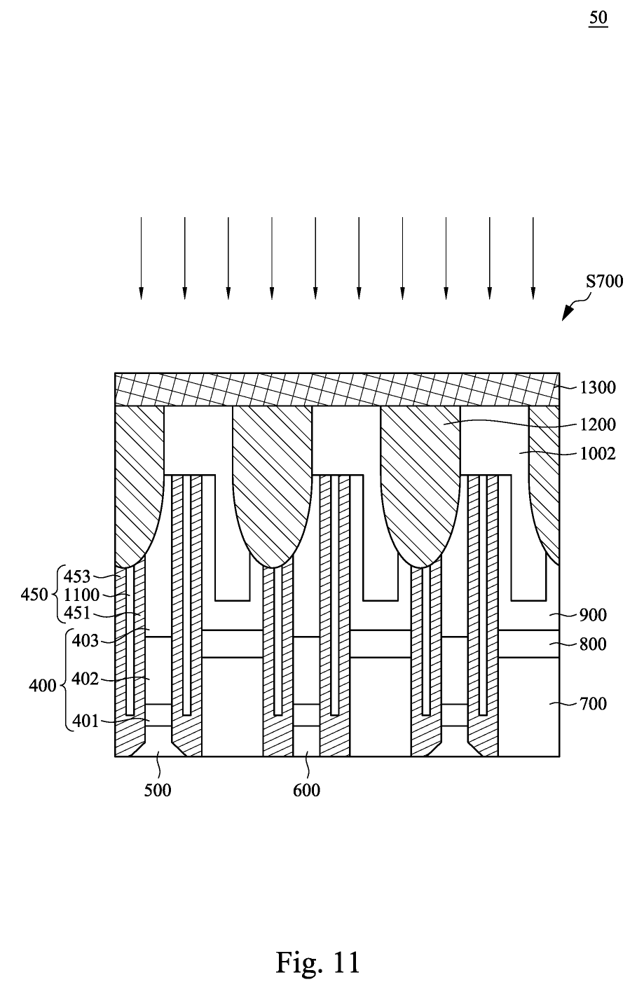

The method M50 proceeds to operation S700 by modifying the first dielectric layer. Referring to FIG. 11, the first dielectric layer 1300 is modified by implanting impurity species into the first dielectric layer 1300, so as to change the etch selectivity of the first dielectric layer 1300. In some embodiments, operation S700 is configured to modify the etch property of the first dielectric layer 1300 such that the isolation layer 1200 has a higher etch resistance to the subsequent etching process than the first dielectric layer 1300.

In some embodiments, operation S700 is an ion implantation. In some embodiments, operation S700 is a plasma treatment. In some embodiments, the first dielectric layer 1300 is implanted with certain species that modify the film selectivity. In some embodiments, the first dielectric layer 1300 is implanted with species that increase the dry etch rate (DER) of the first dielectric layer 1300 during the following etching process. In some embodiments, the first dielectric layer 1300 is implanted with germanium (Ge) and/or nitrogen (N).

In some embodiments, Ge and/or N is distributed in the near surface of the first dielectric layer 1300. In some embodiments, Ge and/or N is distributed approximately 20nm from the surface of the first dielectric layer 1300.

In some embodiments where the impurity species is Ge, the ion implantation is performed with an energy in a range from approximately 20KeV to approximately 25KeV and with a dose of Ge in a range from approximately 3x10¹⁶ (ion/cm²) to approximately 5x10¹⁶ (ion/cm²). In some embodiments, if the energy and the dose are beyond the above ranges, the modified etch property of the first dielectric layer 1300 may not be satisfying.

In some embodiments where the impurity species is N, the ion implantation is performed with an energy in a range from approximately 6KeV to 11KeV and with a dose of N in a range from approximately 3x10¹⁶ (ion/cm²) to approximately 5x10¹⁶ (ion/cm²). In some embodiments, if the energy and the dose are beyond the above ranges, the modified etch property of the first dielectric layer 1300 may not be satisfying.

As mentioned above, the first dielectric layer 1300 may include the same material (e.g., silicon nitride) as the isolation layer 1200, the first spacer layer 451, and the third spacer layer 453. However, because the first dielectric layer 1300 is implanted with Ge and/or N, the Ge concentration and/or N concentration in the first dielectric layer 1300 may be higher than those in the isolation layer 1200, the first spacer layer 451, and the third spacer layer 453.

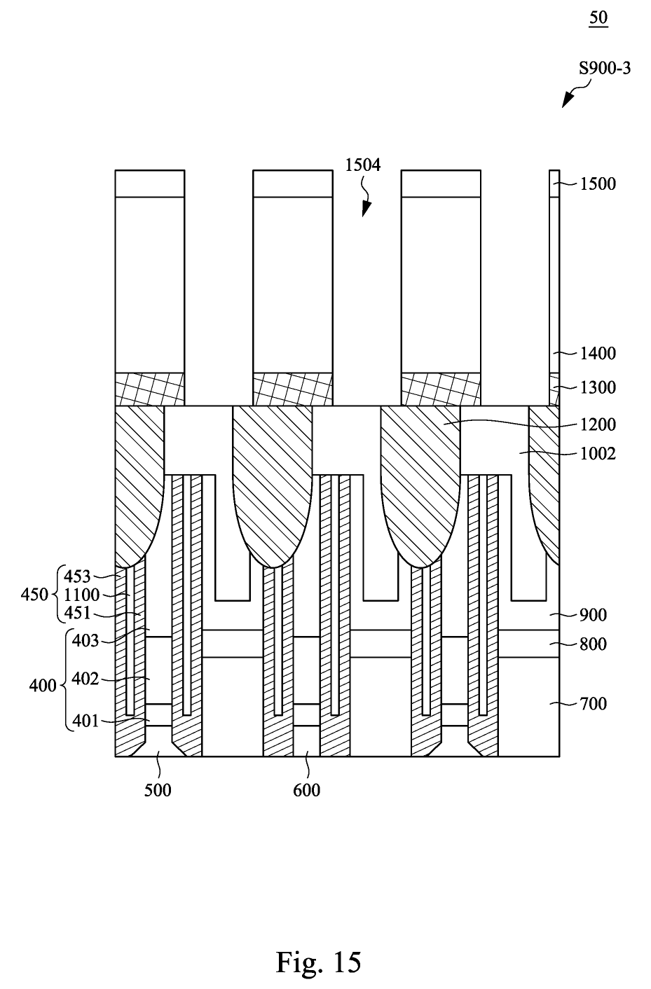

In some embodiments, the dry etch rate of the first dielectric layer 1300 to an etching process (e.g., the etching process discussed in FIG. 15) is increased in a range from approximately 15.9% to approximately 58.6% after the modification. In some embodiments, the selectivity ratio of the dry etch rates between the unmodified and modified first dielectric layer 1300 is in a range of at least approximately 1:1.76 to 1:3.78. That is, the modified first dielectric layer 1300 may have an etch selectivity of at least 1.76 to 3.78 times that of the isolation layer 1200.

In some embodiments, the ion implantation may also drive the impurity species into the top portion of the isolation layer 1200, such that the top portion of the isolation layer 1200 may include higher Ge concentration and/or N concentration than the bottom portion of the isolation layer 1200. In some embodiments, the ion implantation may also drive the impurity species into the top portion of the landing pad 1002, such that the top portion of the landing pad 1002 may include higher Ge concentration and/or N concentration than the bottom portion of the landing pad 1002.

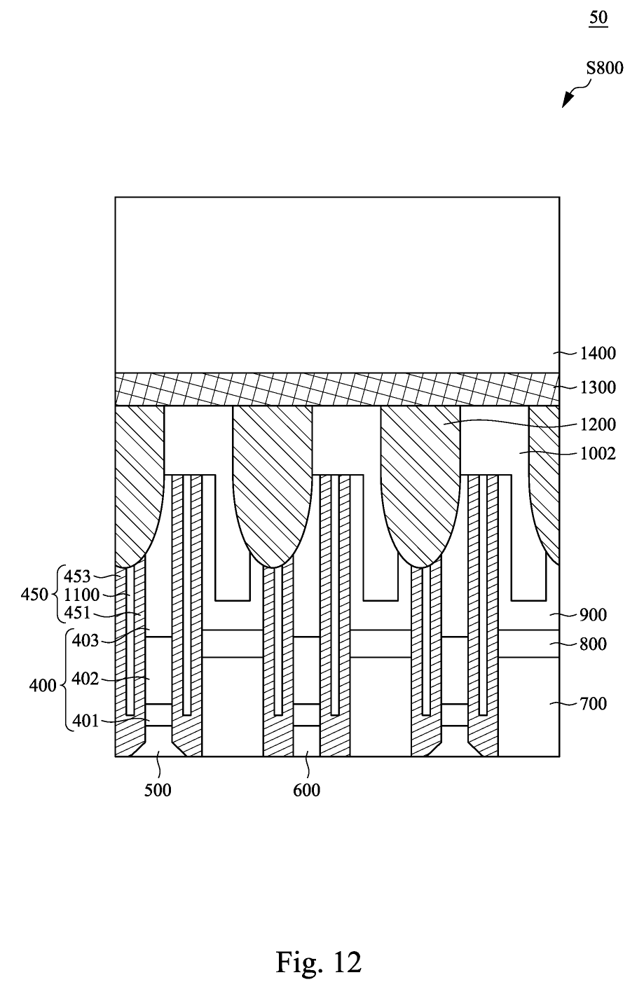

The method M50 proceeds to operation S800 by depositing a second dielectric layer. Referring to FIG. 12, a second dielectric layer 1400 is formed on the modified first dielectric layer 1300. The second dielectric layer 1400 can be deposited by using CVD, ALD, PVD, or other suitable deposition processes. In some embodiments, the second dielectric layer 1400 may include dielectric material. In some embodiments, the second dielectric layer 1400 may include oxides. In some embodiments, the second dielectric layer 1400 has a vertical thickness greater than that of the first dielectric layer 1300.

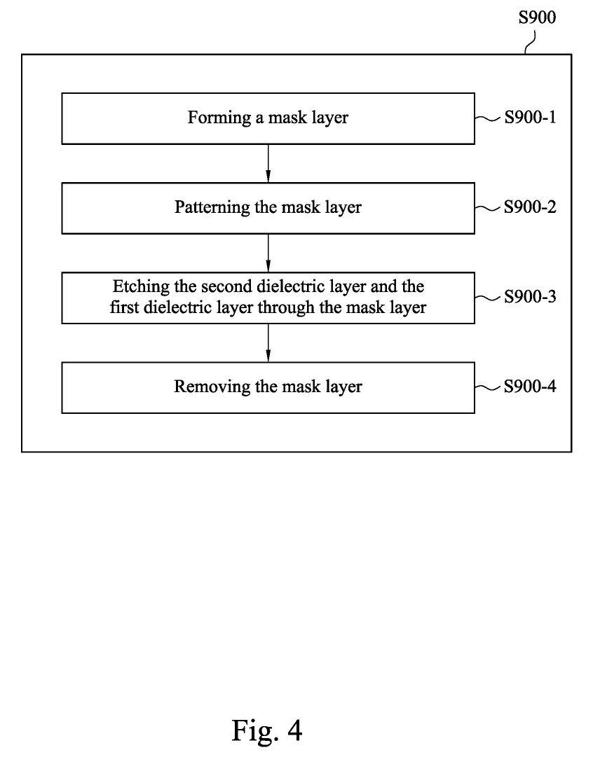

The method M50 proceeds to operation S900 by patterning the first and second dielectric layers to form the second openings. FIG. 4 is a flow chart of patterning the first and second dielectric layers in a method of fabricating a semiconductor device, in accordance with some embodiments of the present disclosure. Referring to FIGS. 4 and 13 to 16, operation S900 may include operations S900-1, S900-2, S900-3 and S900-4. In some embodiments, operation S900 includes photolithography.

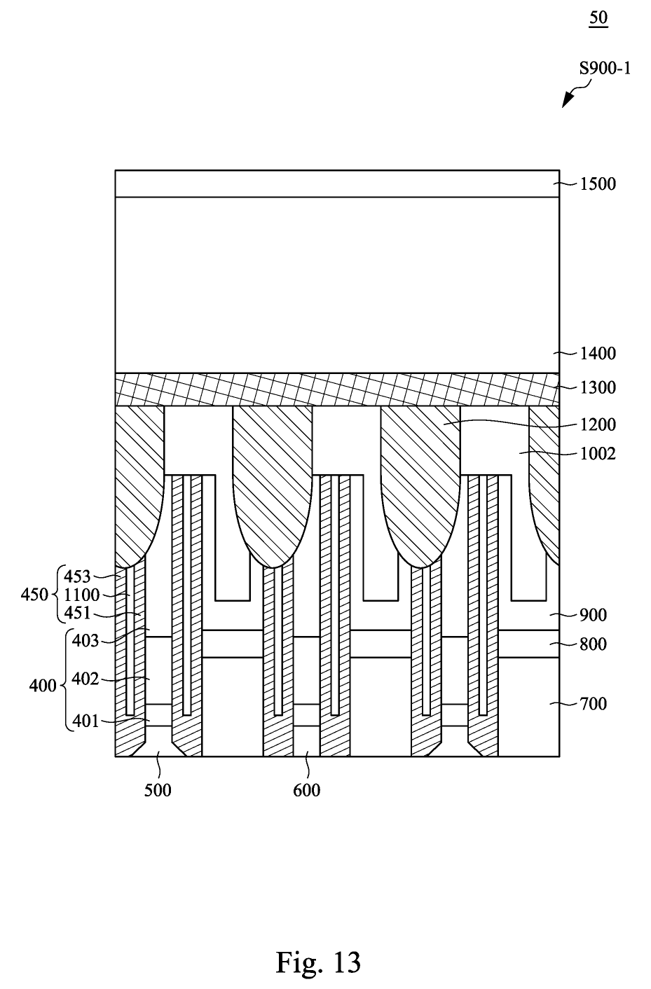

The method M50 proceeds to operation S900-1 by forming a mask layer. Referring to FIG. 13, a mask layer 1500 is formed on the second dielectric layer 1400. In some embodiments, the mask layer 1500 includes a photoresist material. The mask layer 1500 can be formed using suitable deposition processes, such as spin coating.

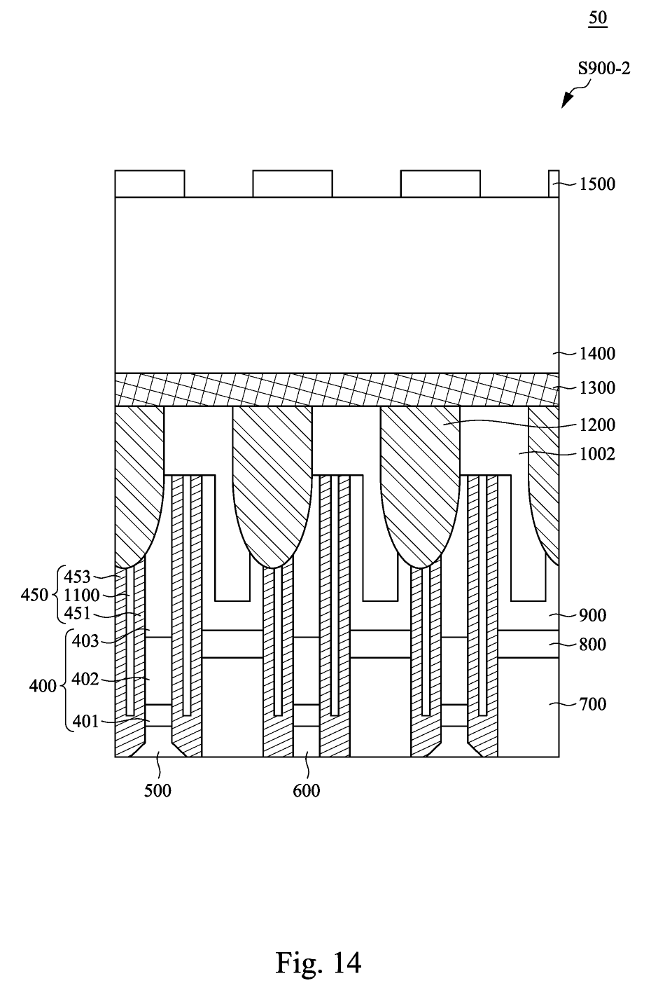

The method M50 proceeds to operation S900-2 by patterning the mask layer. Referring to FIG. 14, the mask layer 1500 is patterned to form openings in the mask layer 1500. The mask layer 1500 is exposed to a light source through a photomask (not shown) that has a specific pattern. In some embodiments, the area of the mask layer 1500 becomes soluble when exposed to light. As a result, the exposed area of the mask layer 1500 can be washed away to define the openings in the mask layer 1500. The patterned mask layer 1500 is configured to act as an etch protector for the underneath second dielectric layer 1400 and the first dielectric layer 1300 in the subsequent etching process.

The method M50 proceeds to operation S900-3 by etching the second dielectric layer and the first dielectric layer through the mask layer. Referring to FIG. 15, the second dielectric layer 1400 and the first dielectric layer 1300 are etched through the patterned mask layer 1500, so as to form the second openings 1504 through the second dielectric layer 1400 and the first dielectric layer 1300. In some embodiments, the second openings 1504 expose the respective landing pads 1002. In some embodiments, the etching process of the operation S900-3 may be performed using etchants of C₄F₆, CH₂F₂, C₄F₈, and O₂.

In some embodiments, during patterning the mask layer 1500, overlay issue may occur, which results in a lateral shift of the second openings 1504 in the first dielectric layer 1300 and the second dielectric layer 1400, and a portion of the isolation layer 1200 may be exposed through the respective second opening 1504. Accordingly, the exposed isolation layer 1200 may be subject to the etching process once the overlying first dielectric layer 1300 is removed. As mentioned above, the isolation layer 1200 and the first dielectric layer 1300 may include the same material, and the etching process may unintentionally remove the exposed isolation layer 1200. However, because the first dielectric layer 1300 has been modified as discussed above, the modified first dielectric layer 1300 may include an increased etch rate to the etching process, creating an etch selectivity to the un-modified isolation layer 1200. As a result, the etching condition can be controlled such that the un-modified isolation layer 1200 may include a higher etching resistance to the etching process, and may act as an etch stop layer for protecting the underlying structure.

However, if the first dielectric layer 1300 is not modified, the first dielectric layer 1300 and the isolation layer 1200, which include the same material, will have approximately the same dry etch rates. In such condition, the etching process may also remove a portion of the isolation layer 1200 or even etch through the isolation layer 1200. The problem with etching through the isolation layer 1200 is that it might open the sealed air gap 1100, causing the subsequent bottom electrode metal of a capacitor structure filling into the air gap 1100, resulting in a possible electrical short and the loss of the air gap 1100 function.

Therefore, the present disclosure provides a method by modifying the first dielectric layer 1300 to have a higher dry etch rate than the isolation layer 1200. In some embodiments, the modified first dielectric layer 1300 and the isolation layer 1200 have considerably different dry etch rates to the etching process. Thus, etching can stop after it finishes etching the modified first dielectric layer 1300 and may avoid a punch through etching of the isolation layer 1200. With such configuration, the device reliability can be improved.

To sum up, with the modified first dielectric layer 1300, even if the second opening 1504 exposes the isolation layer 1200 due to an overlay issue, the isolation layer 1200 may not be etched or may be negligibly etched.

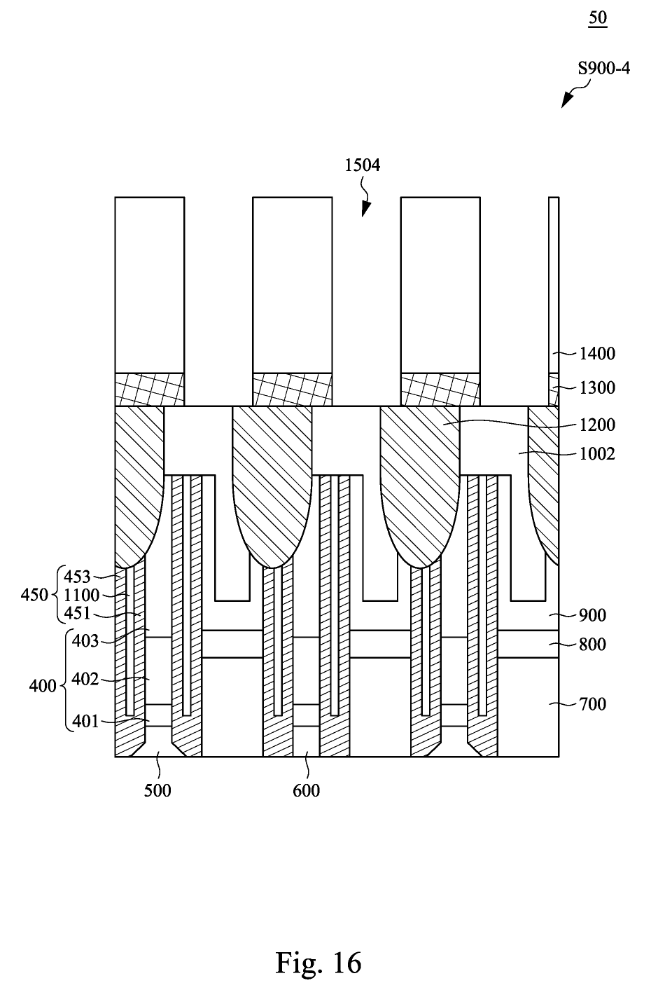

The method M50 proceeds to operation S900-4 by removing the mask layer. Referring to FIG. 16, the mask layer 1500 is removed. In some embodiments, operation S900-4 includes a liquid resist stripper (not shown) that chemically alters the mask layer 1500 so that the mask layer 1500 no longer adheres to the second dielectric layer 1400.

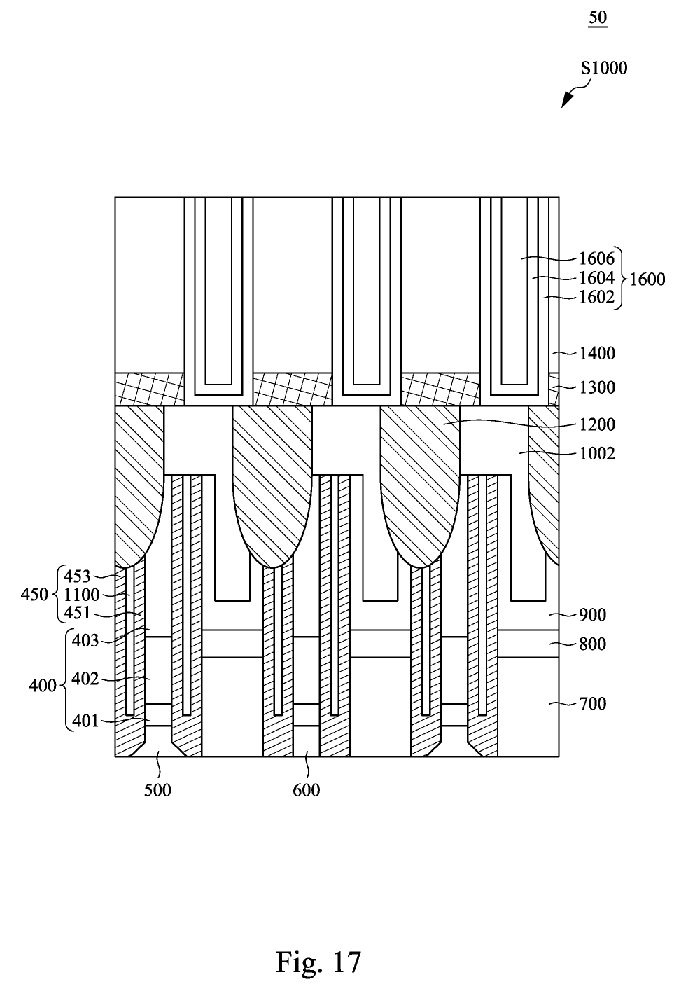

The method M50 proceeds to operation S1000 by forming a capacitor structure on the second openings. Referring to FIG. 17, capacitor structures 1600 are formed in the second openings 1504, respectively. The capacitor structures 1600 may be electrically connected to the underlying structure in the substrate, such as an access transistor (not shown), through the landing pad 1002, the barrier 900, the conductive layer 800, and the contact plug 700. The capacitor structure 1600 may include a bottom electrode 1602, a capacitor dielectric 1604 over the bottom electrode 1602, and a top electrode 1606 over the capacitor dielectric 1604.

In some embodiments, the bottom electrode 1602 and the top electrode 1606 may include conductive material. In some embodiments, the bottom electrode 1602 and the top electrode 1606 may include metal. In some embodiments, the bottom electrode 1602 and the top electrode 1606 may include titanium nitride (TiN). In some embodiments, capacitor dielectric 1604 may include dielectric material. Each of the bottom electrode 1602, capacitor dielectric 1604, and top electrode 1606 may be deposited by using CVD, ALD, PVD, or other suitable deposition process, sequentially.

Referring to FIG. 17, when an overlay issue occurs, the capacitor structure 1600 sits a little bit right on top of the intended landing pads 1002. In some embodiments, the bottom surface of the bottom electrode 1602 touches the top surface of the landing pad 1002 and a small portion of the top surface of the isolation layer 1200.

Based on the above discussion, the critical dimension (CD) of the second opening 1504 in the modified first dielectric layer 1300 may be enlarged to be greater than the CD of the landing pad 1002. That is, a capacitor structure 1600 with a larger CD may be deposited in the enlarged second opening 1504. As a result, the capacitor structure 1600 with a larger CD in an enlarged CD of the second opening 1504 may benefit through having a higher filling capability and a lower contact resistance at the interface between the bottom electrode 1602 of the capacitor structure 1600 and the landing pad 1002. In some embodiments, a lateral width of the second opening 1504 can be greater than a lateral width of the top surface of the landing pad 1002. Therefore, a lateral width of the capacitor structure 1600 can be greater than a lateral width of the top surface of the landing pad 1002.

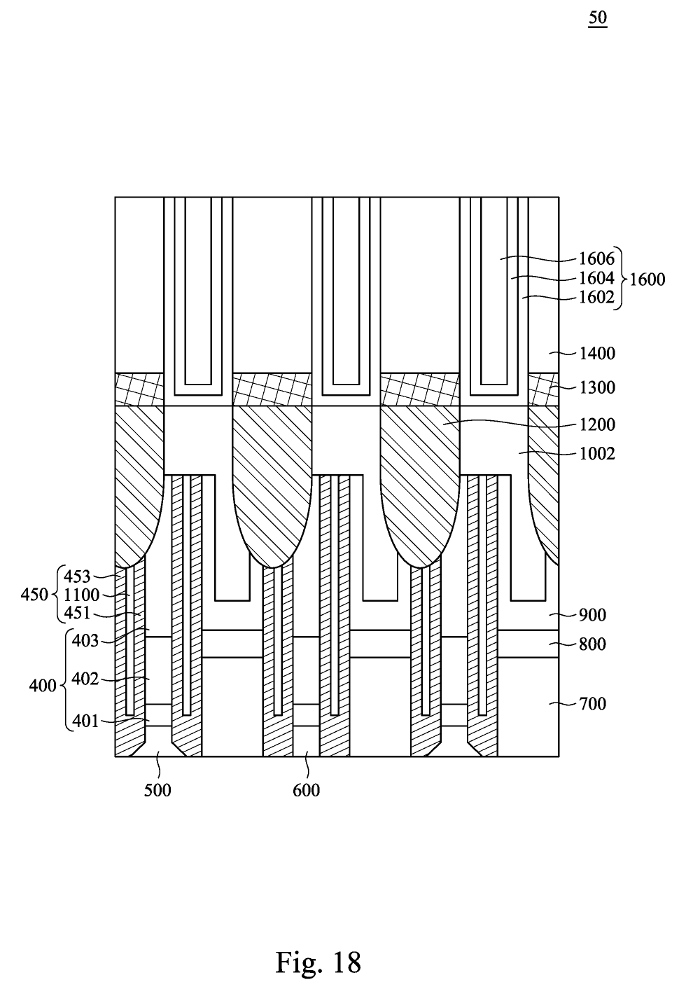

FIG. 18 is a cross-sectional view of a memory cell, in accordance with some embodiments of the present disclosure. FIG. 18 is similar to FIG. 17, and thus relevant details will not be repeated for brevity. FIG. 18 illustrates a condition where no overlay issue occurs, and thus the capacitor structure 1600 sits right on top of the intended landing pad 1002. In some embodiments, the bottom surface of the bottom electrode 1602 completely fits in the top surface of the landing pad 1002.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of fabricating a semiconductor device, comprising:
providing an initial structure, wherein the initial structure comprises:
a bit line structure;
a landing pad adjacent to the bit line structure; and
an isolation layer adjacent to the landing pad;
depositing a first dielectric layer on the initial structure;
modifying an etch property of the first dielectric layer;
performing an etching process on the first dielectric layer to form a first opening; and
forming a capacitor structure in the first opening.

2. The method of claim 1, wherein modifying the etch property of the first dielectric layer comprises implanting an impurity species into the first dielectric layer.

3. The method of claim 2, wherein the impurity species is germanium (Ge).

4. The method of claim 3, wherein the implanting the impurity species into the first dielectric layer is performed with an energy in a range from approximately 20KeV to approximately 25KeV.

5. The method of claim 4, wherein the implanting the impurity species into the first dielectric layer is performed with a dose of Ge in a range from approximately 3x10¹⁶ (ion/cm²) to approximately 5x10¹⁶ (ion/cm²).

6. The method of claim 2, wherein the impurity species is nitrogen (N).

7. The method of claim 6, wherein the implanting the impurity species into the first dielectric layer is performed with an energy in a range from approximately 6KeV to 11KeV.

8. The method of claim 7, wherein the implanting the impurity species into the first dielectric layer is performed with a dose of N in a range from approximately 3x10¹⁶ (ion/cm2) to approximately 5x10¹⁶ (ion/cm²).

9. The method of claim 1, wherein the first dielectric layer and the isolation layer are made with a same material, and wherein modifying the etch property of the first dielectric layer is performed such that the isolation layer has a higher etch resistance to the etching process than the first dielectric layer.

10. The method of claim 1, further comprising depositing a second dielectric layer on the first dielectric layer, wherein the etching process is also performed on the second dielectric layer, such that the first opening is formed in both the first dielectric layer and the second dielectric layer.

11. A semiconductor device, comprising:
a bit line structure;
a landing pad adjacent to the bit line structure;
an isolation layer adjacent to the landing pad;
a first dielectric layer on the isolation layer and the landing pad, wherein the first dielectric layer has a higher germanium (Ge) concentration or a higher nitrogen (N) concentration than the isolation layer; and
a capacitor structure in the first dielectric layer.

12. The semiconductor device of claim 11, wherein the isolation layer and the first dielectric layer are made with a same material.

13. The semiconductor device of claim 12, wherein the same material is silicon nitride.

14. The semiconductor device of claim 11, further comprising a second dielectric layer over the first dielectric layer, wherein the capacitor structure is in the second dielectric layer.

15. The semiconductor device of claim 14, wherein the second dielectric layer comprises a vertical thickness, and wherein the vertical thickness is greater than a vertical thickness of the first dielectric layer.

16. The semiconductor device of claim 11, wherein the capacitor structure is in contact with the isolation layer and the landing pad.

17. The semiconductor device of claim 11, wherein a lateral width of the capacitor structure is greater than a lateral width of a top surface of the landing pad.

18. The semiconductor device of claim 11, further comprising a bit line spacer along a sidewall of the bit line structure, wherein the bit line spacer is made of a same material as the first dielectric layer.

19. The semiconductor device of claim 18, wherein the first dielectric layer has a higher Ge concentration than the bit line spacer.

20. The semiconductor device of claim 18, wherein the first dielectric layer has a higher N concentration than the bit line spacer.
